(19) United States
(12) Patent Application Publication
(10) Pub. No.: US 2008/0265249 A1
(43) Pub. Date: Oct. 30, 2008

(54) STACKED SEMICONDUCTOR DEVICE ASSEMBLY AND PACKAGE

(75) Inventor: Motoaki Sato, Kyoto (JP)

Correspondence Address: STEPTOE & JOHNSON LLP, 1330 CONNECTICUT AVE., NW, WASHINGTON, DC, 20036, US

(73) Assignee: Matsusuhita Electric Industrial Co., Ltd., Kadoma-shi (JP)

(21) Appl. No.: 12/045,271

(22) Filed: Mar. 10, 2008

(30) Foreign Application Priority Data
Apr. 27, 2007 (JP) 2007-117816

(51) Int. Cl. H01L 23/498

(52) U.S. Cl. 257/48; 257/E23.069; 257/E23.002

(57) ABSTRACT

In a stacked semiconductor device assembly, solder balls 2c on the four corners most susceptible to warpage are used as test terminals in the stacked semiconductor device assembly alone, out of solder balls 2a that are used for mounting semiconductor devices on a mounting board 5 and arranged in a grid-like fashion. Thus during packaging, even when warpage occurs in the stacked semiconductor device assembly and causes a faulty connection in these terminals, it is possible to reduce the occurrence of defects in a package because these terminals are not used for operations in the package.

### FIELD OF THE INVENTION

The present invention relates to a stacked semiconductor device assembly including a plurality of stacked semiconductor devices, and a package for packaging the stacked semiconductor device assembly.

### BACKGROUND OF THE INVENTION

Stacked semiconductor device assemblies have been proposed in response to an increase in demand for size reduction and higher functionality of various electronic devices such as mobile phones and digital cameras. In a stacked semiconductor device assembly, electronic components, particularly a plurality of semiconductor devices are stacked and integrated in multiple stages.

In a conventional stacked semiconductor device assembly, upper semiconductor devices are stacked in multiple stages on the wiring board of the lowest semiconductor device with interlayer members such as solder balls interposed among the semiconductor devices. The lowest semiconductor device has a ball grid array (BGA) formed thereon. In the lowest semiconductor device, a semiconductor chip to be mounted is flip-chip bonded via bumps. In the upper semiconductor device, a semiconductor chip is mounted, wire-bonded, and molded with resin on a wiring board having a predetermined wiring circuit formed thereon.

Referring to FIGS. 3A, 3B and 4, the configuration and packaged state of a conventional stacked semiconductor device assembly will be described below.

FIG. 3A is a sectional view showing the configuration of the conventional stacked semiconductor device assembly. FIG. 3B is a back view of a mounting surface showing the configuration of the conventional stacked semiconductor device assembly. FIG. 4 shows that the stacked semiconductor device assembly is mounted on a mounting board.

As shown in FIGS. 3A and 3B, in a second semiconductor device 2, a second semiconductor chip 3b is mounted on a surface of a second wiring board 1b, the second semiconductor chip 3b and the second wiring board 1b are electrically connected to each other by wire bonding, and the second semiconductor chip 3b is molded with molding resin 4. Further, on the underside of the second wiring board 1b, solder balls 2b are electrically connected to the second semiconductor chip 3b by wire bonding and via the internal wiring of the second wiring board 1b. In a first semiconductor device 1, a first semiconductor chip 3a is mounted on a surface of a first wiring board 1a and solder balls 2a acting as external terminals are provided on the underside of the first wiring board 1a. Further, the second semiconductor device is stacked on the first semiconductor device by connecting the solder balls 2b to the surface of the first wiring board. The stacked semiconductor device assembly is configured thus. The solder balls 2a are electrically connected to the first semiconductor chip 3a or the solder balls 2b via the internal wiring of the first wiring board 1a. In such a stacked semiconductor device assembly, warpage may occur because of a difference in coefficient of linear expansion between materials in reflow when the semiconductor devices are stacked.

### DISCLOSURE OF THE INVENTION

In recent years, there have been developed polishing techniques for obtaining thin semiconductor chips and techniques for mounting thin semiconductor chips on wiring boards with high yields to form semiconductor devices Thus a stacked semiconductor device assembly can be formed by stacking thin semiconductor devices in multiple stages. In these techniques, warpage disadvantageously occurs on semiconductor chips, semiconductor devices for mounting semiconductor chips, and a wiring board on which semiconductor devices are stacked. A stacked semiconductor device assembly is mounted on a mounting board via solder balls and thus in order to reduce the height of the stacked semiconductor device assembly mounted on the mounting board, it is necessary to reduce the thicknesses of stacked semiconductor devices or the diameters of solder balls.

However, as shown in FIG. 4, in the case where a height from a surface of the mounting board to the stacked semiconductor device assembly varies due to warpage occurring in the stacked semiconductor device assembly, a sufficient amount of solder cannot be obtained when the solder balls 2a are reduced in diameter. Thus on a point where a height from the surface of a mounting board 5 to the stacked semiconductor device assembly is increased by warpage, solder becomes thin upon bonding, so that the solder balls 2a may have an insufficient bonding strength on the mounting board or the solder balls 2a may be broken. Therefore, warpage in the stacked semiconductor device assembly has to be taken into consideration during packaging, so that packaging has been increasingly dependent upon the packaging skill of a component user.

Further, even when a stacked semiconductor device assembly has excellent electric characteristics, the assembly may become defective as a package due to a faulty connection during packaging.

An object of the present invention is to reduce defects in a package even in the event of warpage in a stacked semiconductor device assembly.

In order to attain the object, a stacked semiconductor device assembly of the present invention includes: a plurality of stacked semiconductor devices; and a plurality of solder balls arranged as external terminals in a grid-like arrangement on the underside opposed to the semiconductor chip mounting surface of the wiring board of the lowest semiconductor device, wherein at least one of the four solder balls formed on the corners of the grid-like arrangement is a terminal having an independent function from the operations of the stacked semiconductor device assembly.

Further, the terminal having the function independent from the operations of the stacked semiconductor device assembly is a test terminal for testing the lowest semiconductor device alone.

Moreover, a package of the present invention is formed by mounting the stacked semiconductor device assembly on a mounting board via the solder balls.

Further, a stacked semiconductor device assembly of the present invention includes: a first semiconductor device; and a second semiconductor device stacked on the first semiconductor device, the second semiconductor device including: a second wiring board; a second semiconductor chip mounted on the major surface of the second wiring board; and a plurality of second solder balls provided on the underside opposed to the major surface of the second wiring board and electrically connected to the second semiconductor chip, the first semiconductor device including: a first wiring board electrically connected to the second semiconductor device via the second solder balls; a first semiconductor chip mounted on the major surface of the first wiring board, the major surface serving as a surface connected to the second semiconductor device; and a plurality of first solder balls arranged as external terminals in a grid-like arrangement on the underside opposed to the major surface of the first wiring board, wherein at least one of the four first solder balls formed on the corners of the grid-like arrangement is a terminal having an independent function from the operations of the stacked semiconductor device assembly.

Further, the terminal having the function independent from the operations of the stacked semiconductor device assembly is a test terminal for testing the first semiconductor device alone.

Moreover, a package of the present invention is formed by mounting the stacked semiconductor device assembly on a mounting board via the first solder balls.

### BRIEF DESCRIPTION OF THE DRAWINGS

FIG. 1A is a sectional view separately showing the configurations of a first semiconductor device and a second semiconductor device;

FIG. 1B is a sectional view showing the configuration of a stacked semiconductor device assembly according to a first embodiment;

FIG. 1C is a back view of the first semiconductor device;

FIG. 2 shows the configuration of a package according to a second embodiment;

FIG. 3A is a sectional view showing the configuration of a conventional stacked semiconductor device assembly;

FIG. 3B is a back view of a mounting surface showing the configuration of the conventional stacked semiconductor device assembly; and

FIG. 4 shows a state in which the stacked semiconductor device assembly is mounted on a mounting board.

### DESCRIPTION OF THE EMBODIMENTS

### First Embodiment

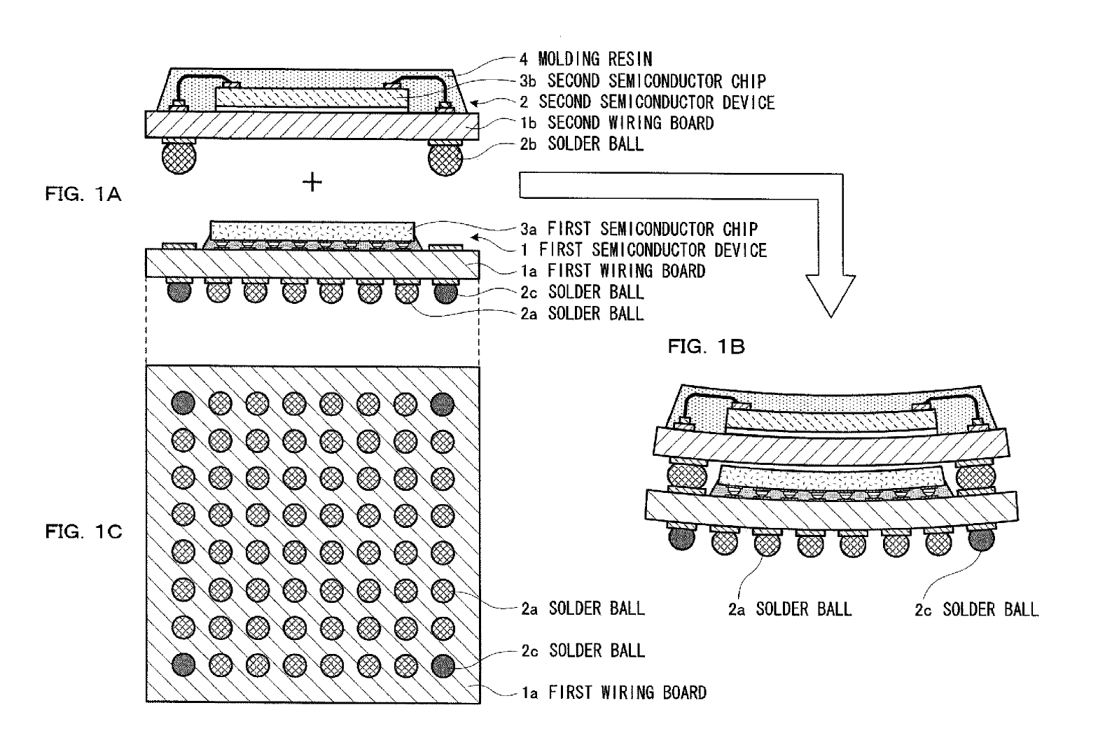

Referring to FIG. 1, a stacked semiconductor device assembly according to a first embodiment of the present invention will now be described.

FIG. 1A is a sectional view separately showing the configurations of a first semiconductor device and a second semiconductor device. FIG. 1B is a sectional view showing the configuration of the stacked semiconductor device assembly according to the first embodiment and is also a sectional view showing the configuration of the stacked semiconductor device assembly in which the second semiconductor device is stacked on the first semiconductor device. FIG. 1C is a back view of the first semiconductor device. FIG. 1C shows the layout of solder balls acting as the external terminals of the stacked semiconductor device assembly.

In the stacked semiconductor device assembly of the present embodiment shown in FIGS. 1A, 1B and 1C, a second semiconductor device 2 is stacked on a first semiconductor device 1. The lower first semiconductor device 1 has a first semiconductor chip 3a flip-chip packaged with underfill resin provided on the major surface of a first wiring board 1a, and has solder balls 2a arranged in a grid-like fashion on the underside opposed to the major surface of the first wiring board 1a. The solder balls 2a act as external electrodes. In the upper second semiconductor device 2, electrical connection is formed by wire bonding for mounting a second wiring board 1b and a second semiconductor chip 3b with the major surface of the second wiring board 1b placed face up, or flip-chip bonding for connecting the second wiring board 1b and the second semiconductor chip 3b by means of interlayer members with the major surface of the second wiring board 1b placed face down. The major surface having the second semiconductor chip 1b formed thereon is mainly protected by molding resin 4. The first semiconductor device 1 including the first semiconductor chip 3a and the second semiconductor device 2 including the second semiconductor chip 3b are separately fabricated beforehand. Before packaging on the board of a product, the electrodes of the semiconductor devices are electrically connected to each other via solder balls 2b to form the stacked semiconductor device assembly.

On the underside opposed to the major surface of the first wiring board 1a, the solder balls 2a acting as external electrodes are arranged in a grid-like fashion. Of the solder balls 2a, at least one of the four solder balls formed on the corners most susceptible to warpage is formed as a solder ball 2c that is a functionally independent terminal not acting on operations in a package in which the stacked semiconductor device assembly is packaged. For example, the solder ball 2c can be used as a test terminal for testing the first semiconductor device 1 alone before stacking.

In this configuration, warpage occurs in the stacked semiconductor device assembly due to a difference in linear expansion between the members when the first semiconductor device 1 and the second semiconductor device 2 are stacked, so that during packaging, a distance between the solder ball 2c and the mounting board is larger than a distance between the other solder balls 2a and the mounting board. Therefore, packaging with the solder ball 2c may cause a problem such as a faulty connection. However, even when warpage occurs in the stacked semiconductor device assembly and causes a defect in the solder ball 2c, it is possible to reduce the occurrence of defects in the package because the solder ball 2c is a terminal not acting on operations after packaging.

### Second Embodiment

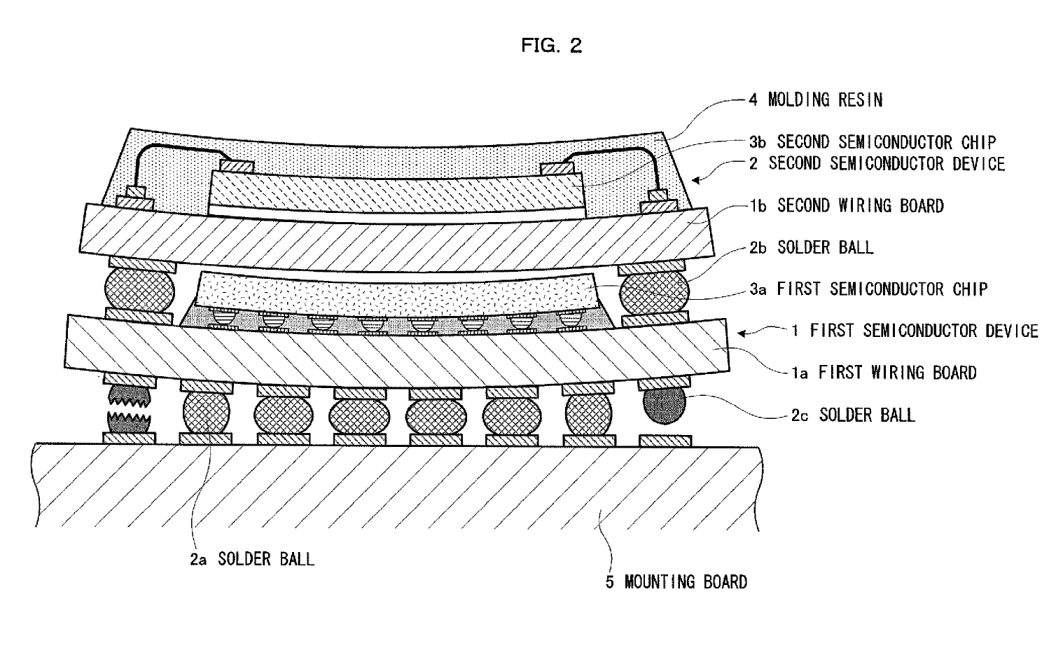

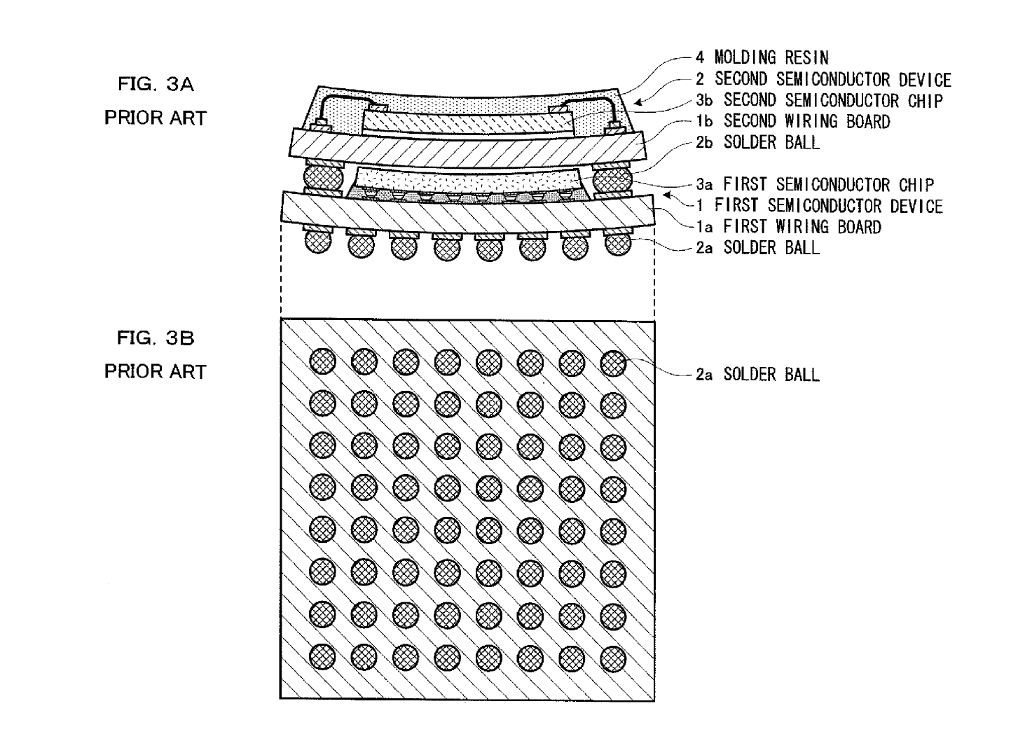

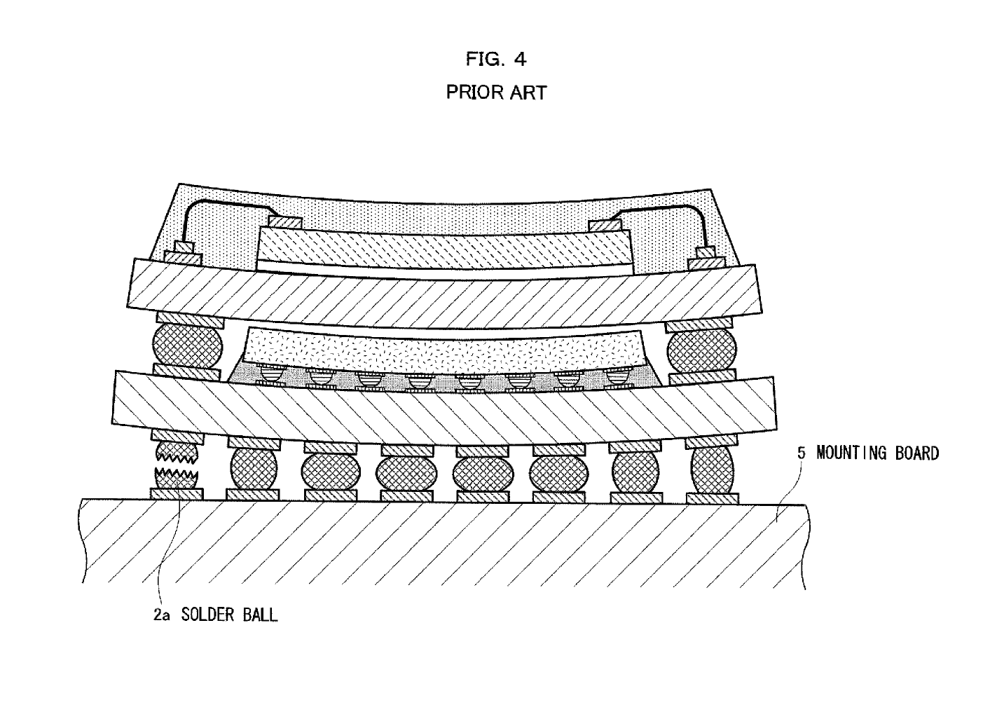

Referring to FIG. 2, the following will describe a package using a stacked semiconductor device assembly according to a second embodiment of the present invention.

FIG. 2 shows the configuration of the package according to the second embodiment. FIG. 2 is a sectional view showing the main part of the configuration in which the stacked semiconductor device assembly of the present invention is mounted on a mounting board.

In the stacked semiconductor device assembly mounted in the package of the present embodiment shown in FIG. 2, a second semiconductor device 2 is stacked on a first semiconductor device 1. The lower first semiconductor device 1 has a first semiconductor chip 3a flip-chip packaged with underfill resin provided on the major surface of a first wiring board 1a, and has solder balls 2a arranged in a grid-like fashion on the underside opposed to the major surface of the first wiring board 1a. The solder balls 2a act as external electrodes. In the upper second semiconductor device 2, electrical connection is formed by wire bonding for mounting a second wiring board 1b and a second semiconductor chip 3b with the major surface of the second wiring board 1b placed face up, or flip-chip bonding for connecting the second wiring board 1b and the second semiconductor chip 3b by means of interlayer members with the major surface of the second wiring board 1b placed face down. The major surface having the second semiconductor chip 3b formed thereon is mainly protected by molding resin 4 The first semiconductor device 1 including the first semiconductor chip 3a and the second semiconductor device 2 including the second semiconductor chip 3b are separately fabricated beforehand. Before packaging on the board of a product, the electrodes of the semiconductor devices are electrically connected to each other via solder balls 2b to form the stacked semiconductor device assembly.

On the underside opposed to the major surface of the first wiring board 1a, the solder balls 2a acting as external electrodes are arranged in a grid-like fashion. Of the solder balls 2a, at least one of the four solder balls formed on the corners most susceptible to warpage is formed as a solder ball 2c that is a functionally independent terminal not acting on operations in the package in which the stacked semiconductor device assembly is packaged. For example, the solder ball 2c can be used as a test terminal for testing the first semiconductor device 1 alone before stacking.

In this configuration, warpage occurs in the stacked semiconductor device assembly due to a difference in linear expansion between the members when the first semiconductor device 1 and the second semiconductor device 2 are stacked. When the stacked semiconductor device assembly is mounted on a mounting board 5 to form the package, a distance between the solder ball 2c and the mounting board 5 is larger than a distance between the other solder balls 2a and the mounting board 5. Therefore, packaging with the solder ball 2c may cause a problem such as a faulty connection. However, even when warpage occurs in the stacked semiconductor device assembly and causes a faulty connection and the like on the solder ball 2c, it is possible to reduce the occurrence of defects in the package because the solder ball 2c is a terminal not acting on the operations of the package after packaging.

In this state, the stacked semiconductor device assembly is mounted on the mounting board 5 by reflowing. When the stacked semiconductor device assembly is joined to the mounting board 5, the solder ball 2c has the largest internal stress because the first wiring board 1a is warped due to a difference in linear expansion from a high-temperature melting process to a solidification/cooling process during packaging. Thus the solder ball 2c may not be connected to the mounting board 5 or have a lower connection strength than the other solder balls Therefore, even when the solder hall 2c is connected to the mounting board 5, the solder ball 2c has a small cross-sectional area on the joint and can be easily broken on purpose. In a state in which the solder ball 2c is not connected to the mounting board 5, the largest stress to be applied to the solder ball 2c is released and spread over the solder balls 2a. Thus the solder balls are connected stronger than a state in which the solder ball 2c is connected.

In the foregoing embodiments, the two semiconductor devices are stacked. Also in the case where semiconductor devices are stacked in multiple layers, solder balls on four corners most susceptible to warpage are caused to act as inactive terminals in a package, out of solder balls used for mounting the semiconductor devices to a mounting board and arranged in a grid-like fashion. Thus during packaging, even when warpage occurs in a stacked semiconductor device assembly and causes a faulty connection in these terminals, it is possible to reduce the occurrence of defects in the package because these terminals are not used for operations in the package.

What is claimed is:

1. A stacked semiconductor device assembly, comprising:
a plurality of stacked semiconductor devices; and
a plurality of solder balls arranged as external terminals in a grid-like arrangement on an underside opposed to a semiconductor chip mounting surface of a wiring board of the lowest semiconductor device,
wherein at least one of the four solder balls formed on corners of the grid-like arrangement is a terminal having an independent function from operations of the stacked semiconductor device assembly.

2. The stacked semiconductor device assembly according to claim 1, wherein the terminal having the function independent from the operations of the stacked semiconductor device assembly is a test terminal for testing the lowest semiconductor device alone.

3. A stacked semiconductor device assembly, comprising:
a first semiconductor device; and
a second semiconductor device stacked on the first semiconductor device,
the second semiconductor device comprising:
a second wiring board;
a second semiconductor chip mounted on a major surface of the second wiring board; and
a plurality of second solder balls provided on an underside opposed to the major surface of the second wiring board and electrically connected to the second semiconductor chip,
the first semiconductor device comprising:
a first wiring board electrically connected to the second semiconductor device via the second solder balls;
a first semiconductor chip mounted on a major surface of the first wiring board, the major surface serving as a surface connected to the second semiconductor device; and
a plurality of first solder balls arranged as external terminals in a grid-like arrangement on an underside opposed to the major surface of the first wiring board,
wherein at least one of the four first solder balls formed on corners of the grid-like arrangement is a terminal having an independent function from operations of the stacked semiconductor device assembly.

4. The stacked semiconductor device assembly according to claim 3, wherein the terminal having the function independent from the operations of the stacked semiconductor device assembly is a test terminal for testing the first semiconductor device alone.

5. A package formed by mounting the stacked semiconductor device assembly according to claim 1 on a mounting board via the solder balls.

6. A package formed by mounting the stacked semiconductor device assembly according to claim 2 on a mounting board via the solder balls.

7. A package formed by mounting the stacked semiconductor device assembly according to claim 3 on a mounting board via the first solder balls.

8. A package formed by mounting the stacked semiconductor device assembly according to claim 4 on a mounting board via the first solder balls.
